(19) United States
(12) Patent Application Publication
(10) Pub. No.: US 2025/0147076 A1
(43) Pub. Date: May 8, 2025

(54) Current Sensor And Current Control System

(71) Applicant: Alps Alpine Co., Ltd., Tokyo (JP)

(72) Inventors: Keisuke NAKAYAMA, Miyagi-ken (JP); Hirofumi OKUMURA, Miyagi-ken (JP); Manabu TAMURA, Miyagi-ken (JP); Hideaki TAKANO, Miyagi-ken (JP)

(21) Appl. No.: 19/013,020

(22) Filed: Jan. 8, 2025

Related U.S. Application Data
(63) Continuation of application No. PCT/JP2023/006393, filed on Feb. 22, 2023.

(30) Foreign Application Priority Data
Aug. 8, 2022 (JP) 2022-126454

(51) Int. Cl. G01R 15/20

(52) U.S. Cl. CPC G01R 15/207

(57) ABSTRACT

A current sensor includes busbars through which a current to be measured flows, magnetic detectors capable of detecting a magnetic field generated when the current to be measured flows through the busbars, a storage space storing the magnetic detectors, and a housing with which part of the busbars is integrated. Ends of the busbars are connected to an external first unit including a cooling device, and other ends of the busbars are connected to an external second unit whose temperature becomes higher than that of the first unit when the current to be measured flows. In the current sensor, which is capable of measuring a current value of the current to be measured from a result of the detection performed by the magnetic detectors, the housing has first vents penetrating from the inside of the storage space to the outside on a side facing the first unit.

### CLAIM OF PRIORITY

This application is a Continuation of International Application No. PCT/JP2023/006393 filed on Feb. 22, 2023, which claims benefit of Japanese Patent Application No. 2022-126454 filed on Aug. 8, 2022. The entire contents of each application noted above are hereby incorporated by reference.

### BACKGROUND OF THE INVENTION

### 1. Field of the Invention

The present invention relates to a current sensor that detects a magnetic field generated by a current to be measured flowing through busbars and that measures a current value of the current to be measured from the detected magnetic field.

### 2. Description of the Related Art

In recent years, increasing demand for decarbonization has led to a shift from engines to motors, that is, a shift away from gasoline vehicles and conversion to electric power (EV shift), in order to reduce CO₂ emissions when driving automobiles. As current measuring devices that measure currents supplied to three-phase motors, current sensors are used (e.g., Japanese Patent No. 6462850).

As the EV shift spreads to large commercial vehicles such as trucks and buses, motor capacities in hybrid and electric automobiles are increasing, and currents to be measured by current sensors used for motor control are also increasing. Motors are increasingly being driven continuously under high load conditions, and continuously flowing currents are becoming larger. Busbars, which are current paths of currents to be measured, generate heat in an amount proportional to a square of magnitude of a current. As continuously flowing currents to be measured become larger, therefore, the amount of heat generated by the busbars increases, thereby increasing temperature of electronic components such as magnetic detectors located near the busbars.

### SUMMARY OF THE INVENTION

Because a current sensor described in Japanese Patent No. 6462850 includes a substrate including electronic components in a storage space closed by a case member, it is difficult to discharge heat generated by busbars to the outside of the storage space. The amount of heat generated by the busbars, therefore, increases, and temperature in the storage space might exceed a heat resistance temperature of magnetic detectors, thereby reducing measurement accuracy of the current sensor or shortening product life.

The present invention, therefore, provides a current sensor capable of discharging air heated by heat generated by busbars to the outside of a storage space in order to suppress an increase in temperature around electronic components such as magnetic detectors and suitable for measurement of a large current.

The present invention includes the following configurations as means for solving the above-described problem.

A current sensor includes a busbar through which a current to be measured flows, a magnetic detector capable of detecting a magnetic field generated when the current to be measured flows through the busbar, and a housing that has a storage space storing the magnetic detector and with which part of the busbar is integrated. The current sensor is capable of measuring a current value of the current to be measured from the magnetic field detected by the magnetic detector. An end of the busbar is connected to an external first unit including a cooling device and another end of the busbar is connected to an external second unit whose temperature is higher than temperature of the first unit. The housing has a first vent penetrating from an inside of the storage space to an outside on a side facing the first unit.

Since the first vent is provided in an area of the housing facing the first unit, airflow is caused by a difference in temperature between the busbar and the first unit when the busbar generates heat, and air in the housing heated by the heat generated by the busbar is discharged to the outside of the storage space, thereby suppressing an increase in temperature in the housing.

The housing may have, in addition to the first vent, a second vent penetrating from the inside of the storage space to the outside on a side facing the second unit.

Since the temperature of the second unit is higher than that of the first unit, airflow is caused between the first unit and the second unit. By providing the second vent facing the second unit in addition to the first vent facing the first unit, therefore, air flowing between the first unit and the second unit tends to pass through the storage space in the housing. Air in the storage space heated by heat generated by the busbar, therefore, can be discharged (heat exhaust) to the outside of the storage space using the airflow caused by the difference in temperature between the first unit and the second unit.

In this case, the magnetic detector may be arranged between the first vent and the second vent. With this configuration, air around the magnetic detector heated by heat generated by the busbar can be efficiently discharged from the housing using the airflow between the first vent and the second vent. It is therefore possible to suppress an increase in temperature of the magnetic detector and prevent deterioration of measurement accuracy of the magnetic detector.

The magnetic detector may be arranged at a position facing the busbar. When the magnetic detector is viewed as facing the busbar, that is, viewed in a direction perpendicular to a plate surface of the busbar facing the magnetic detector, at least part of the magnetic detector may overlap the busbar. As a result, the magnetic detector can efficiently detect a magnetic field of the busbar.

The current sensor may further include plate-like shielding members capable of suppressing disturbance noise applied to the magnetic detector. The shielding members may include a first shielding member arranged on a side of the magnetic detector opposite a side on which the busbar is arranged and a second shielding member paired with the first shielding member and arranged on a side of the busbar opposite a side on which the magnetic detector is arranged.

Since the shielding members can suppress disturbance noise applied to the magnetic detector, detection accuracy of the current sensor improves.

The current sensor may further include a shielding member capable of suppressing disturbance noise applied to the magnetic detector. A cross-sectional shape of the shielding member when cut along a surface perpendicular to a direction in which the busbar extends may be a U-shape, and the shielding member may be arranged in such a way as to surround, when viewed in the direction in which the busbar extends, the busbar from both sides of the busbar in a direction perpendicular to a direction in which the busbar and the magnetic detector overlap and a side of the busbar opposite a side in the direction in which the busbar and the magnetic detector overlap on which the magnetic detector is arranged.

Since the U-shaped shielding member surrounding the busbar from the three sides other than the side on which the magnetic detector is arranged is used, when a plurality of busbars is provided, an effect of noise from the busbars other than the one that the magnetic detector faces can be suppressed.

The current sensor may further include an electronic component different from the magnetic detector. The electronic component may be arranged in the storage space. With this configuration, an effect of heat generated by the busbar upon the electronic component in addition to the magnetic detector can be suppressed.

A current control system includes the current sensor in the present invention, the first unit, and the second unit. The first unit may be an inverter including the cooling device, and the second unit may be a motor.

With this configuration, it is possible to discharge air in the storage space heated by heat generated by the busbar to the outside of the storage space using airflow caused between the first unit, whose temperature is relatively low, and the second unit, whose temperature is relatively high, and suppress an increase in temperature around the magnetic detector.

According to the present invention, air in a storage space heated by heat generated by busbars can be discharged to the outside of the storage space using airflow caused by a difference in temperature near a current sensor. As a result, it is possible to suppress an increase in temperature of magnetic detectors due to heat generated by the busbars and provide a current sensor with excellent measurement accuracy.

### BRIEF DESCRIPTION OF THE DRAWINGS

FIG. 1 is a perspective view of a current sensor according to an embodiment of the present invention;

FIG. 2 is a perspective view illustrating a state where a cover member and a substrate are omitted from the current sensor according to the embodiment of the present invention;

FIG. 3 is a cross-sectional view of the current sensor of FIG. 1;

FIG. 4 is a block diagram of a current control system including the current sensor of FIG. 1;

FIG. 5 is a block diagram of a current control system according to a modification;

FIG. 6 is a perspective view illustrating a state where a cover member and a substrate are omitted from a current sensor according to another modification;

FIG. 7 is a perspective view of a current sensor according to another modification;

FIG. 8 is a cross-sectional view of the current sensor of FIG. 7;

FIG. 9 is a perspective view of a current sensor according to another modification;

FIG. 10 is a cross-sectional view of a current sensor according to another modification;

FIG. 11 is a cross-sectional view of a current sensor according to another modification;

FIG. 12 is a perspective view of a conventional current sensor; and

FIG. 13 is a cross-sectional view of the current sensor of FIG. 12.

### DESCRIPTION OF THE PREFERRED EMBODIMENTS

An embodiment of the present invention will be described hereinafter with reference to the accompanying drawings. In the drawings, the same members are given the same numbers, and description thereof is omitted. In order to indicate a positional relationship between members, reference coordinates are shown in each drawing. The reference coordinates include an X-axis direction, in which busbars extend, a Y-axis direction, which is perpendicular to the X-axis direction on plate surfaces of the busbars, and a Z-axis direction, which is a direction perpendicular to the plate surfaces of the busbars.

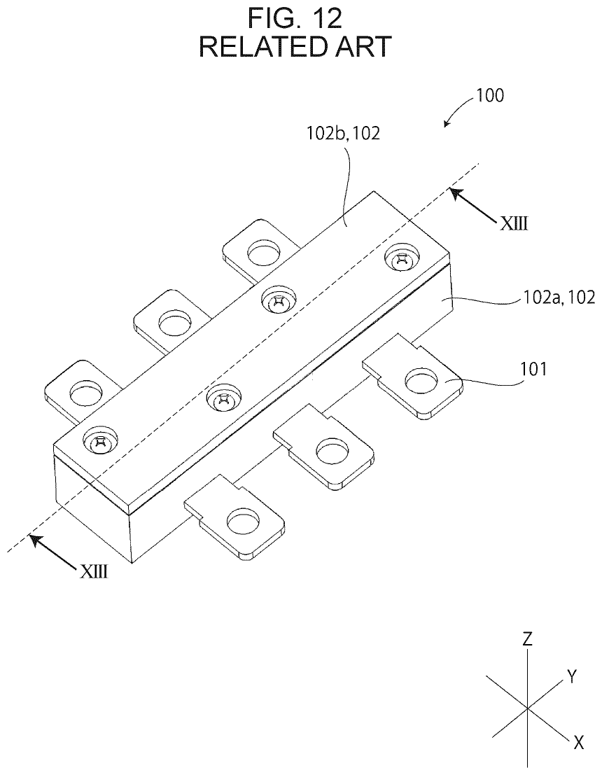

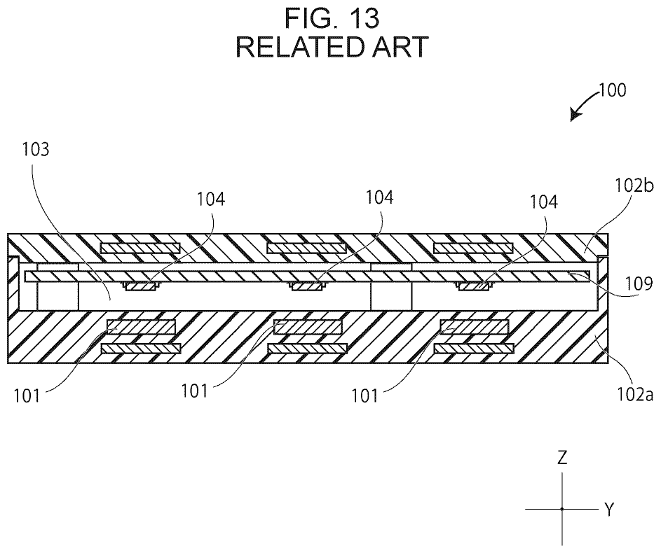

FIG. 12 is a perspective view of a conventional current sensor 100, and FIG. 13 is a cross-sectional view cut from the current sensor 100 of FIG. 12 in a YZ plane along line XIII-XIII. As illustrated in these drawings, in the conventional current sensor 100, a substrate 109 including three magnetic detectors 104 is provided in a storage space 103 in a housing 102 formed by a case member 102a with which part of busbars 101 is integrated and a cover member 102b.

The storage space 103 is defined by the housing 102, and because there is usually no gap large enough to cause air convection, heat generated by the busbars 101 is trapped inside. When a current to be measured continuously flowing through the busbars 101 becomes large, therefore, temperature in the storage space 103 increases due to an effect of heat generated by the busbars 101 and might exceed a heat resistance temperature of the magnetic detectors 104, thereby reducing detection accuracy of the current sensor 100.

When the current sensor 100 measures a current flowing between an inverter and a motor, ends of the busbars 101 are connected to the inverter, and other ends of the busbars 101 are connected to the motor. The inverter includes a cooling device that cools an insulated gate bipolar transistor (IGBT). When a current to be measured flows through the busbars 101, therefore, the motor becomes, for example, about 170° C. to 180° C. and the inverter becomes 100° C. or lower, that is, temperature of the inverter becomes lower than that of the motor. As a result, airflow (convection) is caused near the current sensor 100 due to the difference in temperature between the motor and the inverter.

The present invention aims to prevent an increase in temperature of the magnetic detectors 104 and suppress a decrease in the detection accuracy of the current sensor 100 by discharging air inside the storage space 103 heated by heat generated by busbars to the outside of the storage space 103 using airflow caused by a difference in temperature around the current sensor.

### Current Sensor

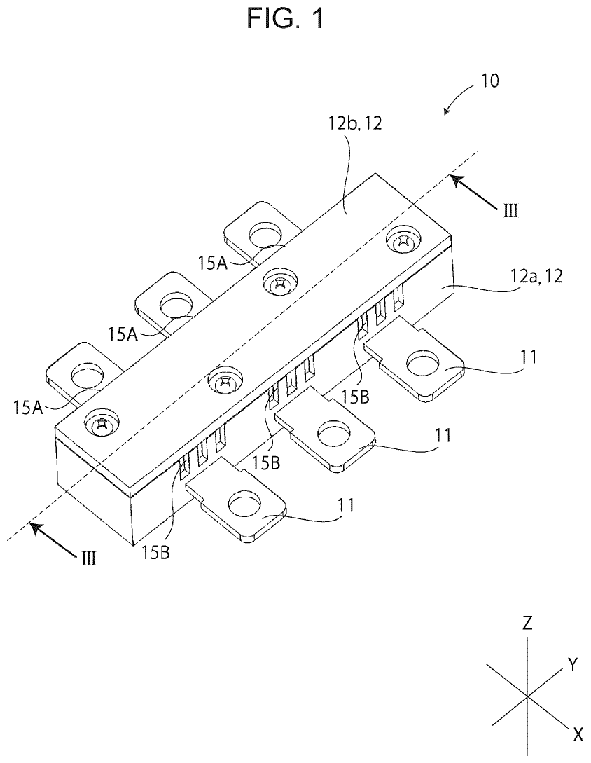

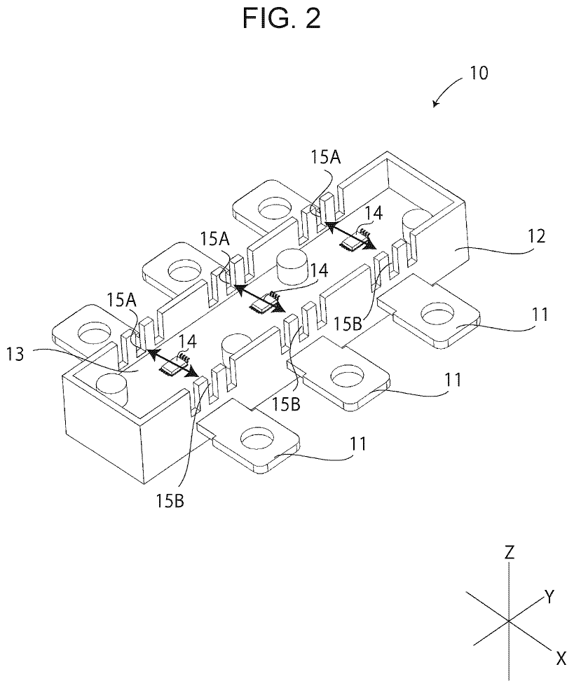

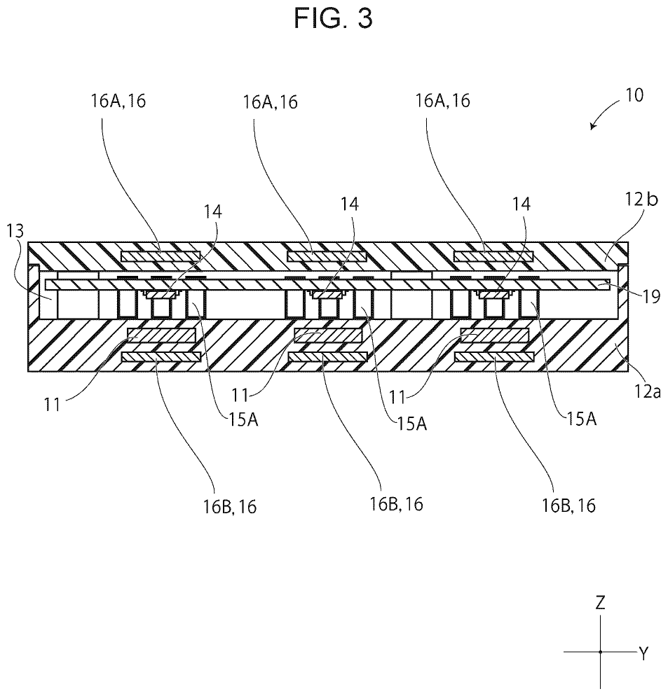

FIG. 1 is a perspective view of a current sensor 10 according to an embodiment of the present invention, and FIG. 2 is a perspective view illustrating a state where a cover member 12b and a substrate 19 (see FIG. 3) are omitted from the current sensor 10. FIG. 3 is a cross-sectional view cut from the current sensor 10 of FIG. 1 in a YZ plane along line III-III.

The current sensor 10 includes three busbars 11 arranged side-by-side in the Y-axis direction, a case member 12a, and a cover member 12b, and has a storage space 13 in a housing 12 formed by the case member 12a and the cover member 12b. In the storage space 13, magnetic detectors 14 capable of detecting a magnetic field generated when a current to be measured flow through the busbars 11.

The busbars 11 are plate-like conductive members linearly extending in a width direction (X-axis direction) of the housing 12, and part thereof is integrated with the case member 12a through insert molding or the like. A current to be measured, which is a detection target, flows through the busbars 11, which are composed of, for example, copper, brass, aluminum, or the like. Two opposite plate surfaces of each of the busbars 11 are provided in correspondence with a top and a bottom (both surfaces in the Z-axis direction) of the housing 12.

Both ends of each busbar 11 in the X-axis direction, which are connections to the outside, need not be linearly symmetrical about the Y-axis. In addition, part of each busbar 11 that is not facing the corresponding magnetic detector 14 need not be a flat plate, and, for example, may be bent, instead.

The magnetic detectors 14 detect a magnetic field (induced magnetic field) generated when a current to be measured flows through the busbars 11 and measure a current value of the current to be measured. As the magnetic detectors 14, for example, magnetoresistance elements, such as GMR (giant magnetoresistance) elements or TMR (tunnel magnetoresistance) elements, that use a magnetoresistance effect, where electrical resistance changes due to an external magnetic field, are used. The substrate 19 has plate surfaces parallel to an XY plane, and the magnetic detectors 14 are arranged on one of the plate surfaces of the substrate 19, which is arranged in the storage space 13, at positions facing the corresponding busbars 11. At least part of sensor portions of the magnetic detectors 14 faces the corresponding busbars 11 and overlaps the busbars 11 when viewed in the Z-axis. The three magnetic detectors 14 are preferably provided on the same side of the substrate 19.

As illustrated in FIG. 3, in the current sensor 10, plate-like shielding members 16 including a first shielding member 16A and a second shielding member 16B are provided for each of the three sets of a busbar 11 and a magnetic detector 14. The first shielding members 16A and the second shielding members 16B are each formed, for example, by stacking a plurality of plate-like metal members having the same shape on one another. Each set of the shielding members 16 may include only the first shielding member 16A or the second shielding member 16B, instead.

The first shielding members 16A are integrated with the cover member 12b, and arranged on a side of the magnetic detectors 14 opposite a side on which the busbars 11 are arranged. The second shielding members 16B are integrated with the case member 12a, and arranged on a side of the busbars 11 opposite a side on which the magnetic detectors 14 are arranged. Because the first shielding members 16A and second shielding members 16B suppress an effect of disturbance noise on the magnetic detectors 14, the detection accuracy of the current sensor 10 improves.

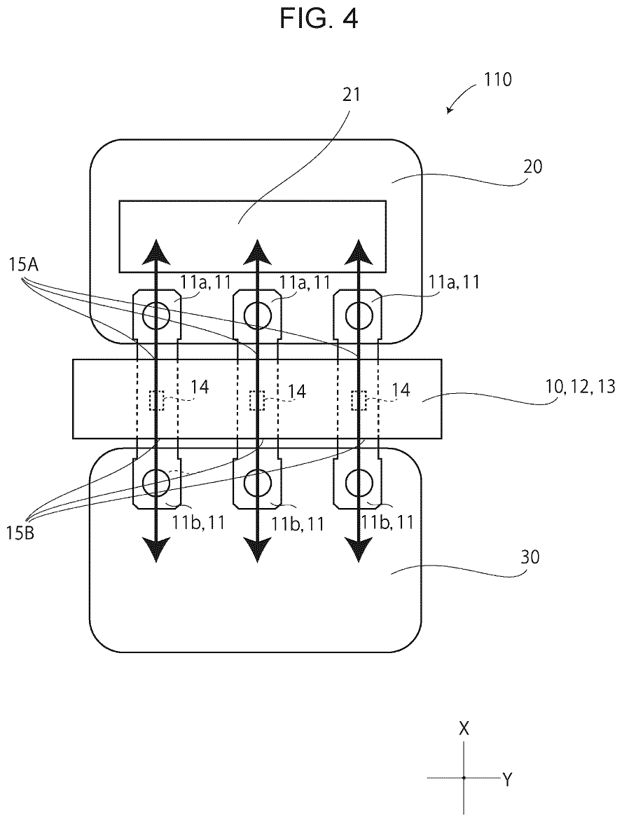

FIG. 4 is a block diagram illustrating a current control system 110 including the current sensor 10 of FIG. 1.

As illustrated in the drawing, the present invention can be implemented as a current control system 110 including the current sensor 10, a first unit 20, and a second unit 30, whose temperature is higher than that of the first unit. When a current flowing between an inverter and a motor of an automobile is measured using the current sensor 10, for example, the first unit 20 is the inverter including a cooling device 21 and the second unit 30 is the motor. In this case, the motor becomes 170° C. to 180° C. and the inverter becomes 100° C. or lower, for example, and air moves near the current sensor 10 due to the difference in temperature.

Ends 11a of the busbars 11 of the current sensor 10 are connected to the external first unit 20 including the cooling device 21, and other ends 11b are connected to the second unit 30. Since the temperature of the second unit 30 is higher than that of the first unit 20, airflow (convection) caused by the difference in temperature is caused in a direction (X-axis direction) indicated in FIG. 4 by two-way arrows.

As illustrated in FIGS. 2 and 4, the housing 12 has first vents 15A penetrating from the inside of the storage space 13 to the outside on a side facing the first unit 20. The housing 12 also has second vents 15B penetrating from the inside of the storage space 13 to the outside on a side facing the second unit 30. Part of airflow in the X-axis direction due to the difference in temperature passes through the storage space 13 of the housing 12 via the first vents 15A and the second vents 15B. Even when air in the storage space 13 becomes hot due to heat generated by the busbars 11, therefore, the hot air can be discharged to the outside of the storage space 13 using the airflow caused by the difference in temperature, and it is possible to prevent an increase in temperature of the magnetic detectors 14 and maintain the detection accuracy of the current sensor 10.

From the perspective of taking air outside the storage space 13 into the vicinity of the magnetic detectors 14 and preventing hot air from remaining in the storage space 13, it is preferable to arrange the magnetic detectors 14 between the first vents 15A and the second vents 15B. With this configuration, when a large current continuously flows as a current to be measured, it is possible to keep heat generated by the busbars 11 from affecting the magnetic detectors 14 and keep measurement accuracy of the current sensor 10 high.

Arranging the magnetic detectors 14 between the first vents 15A and the second vents 15B means that at least part of the magnetic detectors 14 is located on line segments connecting the first vents 15A and the second vents 15B. The line segments connecting the first vents 15A and the second vents 15B refer to line segments whose dots on ends thereof are located in any areas of the first vents 15A and the second vents 15B.

As illustrated in FIGS. 1 to 3, the first vents 15A and the second vents 15B are sets of three elongated rectangular holes whose longitudinal direction is the Z-axis direction. Since the first vents 15A and the second vents 15B are configured as a plurality of slits arranged side-by-side, it is possible to cool the storage space 13 using airflow caused by a difference in temperature and prevent foreign objects from entering the storage space 13.

In the current sensor 10, three sets of first vents 15A and three sets of second vents 15B are provided, which is as many as the number of busbars 11 and the number of magnetic detectors 14. The number of first vents 15A and the number second vents 15B, however, are not limited to three, and may be different from the number of busbars 11 and the number of magnetic detectors 14.

### First Modification

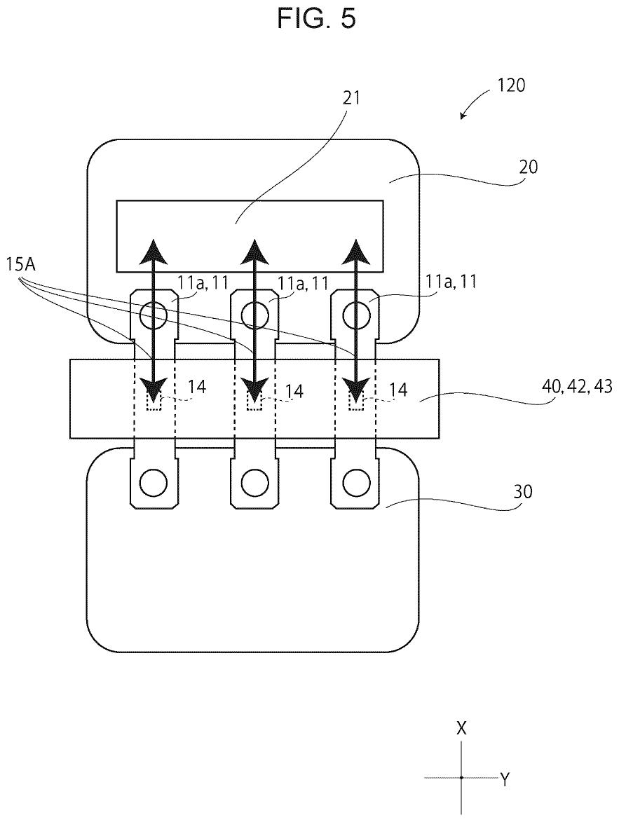

FIG. 5 is a block diagram illustrating a current control system 120 including a current sensor 40 according to a modification.

The housing 12 of the current sensor 10 described above has the first vents 15A and the second vents 15B and uses airflow caused by a difference in temperature between the first unit 20 and the second unit 30 to discharge hot air in the storage space 13 to the outside. The current sensor 40, on the other hand, is different from the current sensor 10 in that the current sensor 40 has only first vents 15A facing, among the first unit 20 and the second unit 30 to which the busbars 11 are connected, the first unit 20 whose temperature is relatively low.

When a storage space 43 of a housing 42 has only the first vents 15A facing the first unit 20 like the current sensor 40 and air in the storage space 43 becomes hot due to heat generated by the busbars 11 in the housing 42, a difference in temperature is caused between the busbars 11 and the first unit 20. As a result, airflow is caused by the difference in temperature in a direction of two-way arrows illustrated in FIG. 5, that is, in the X-axis direction. As with the current sensor 10, therefore, it is possible to discharge air heated by heat in the storage space 43 to the outside using airflow caused by the difference in temperature between the first unit 20 and the busbars 11 and suppress a decrease in the measurement accuracy of the current sensor 40 caused by an increase in temperature of the magnetic detectors 14.

Although air in the storage space 43 is discharged to the outside even when vents are provided only at positions that do not face the first unit 20, efficient ventilation can be performed by providing vents (first vents 15A) at positions facing the first unit 20. When only second vents 15B are provided, ventilation efficiency is lower than in the first modification.

### Second Modification

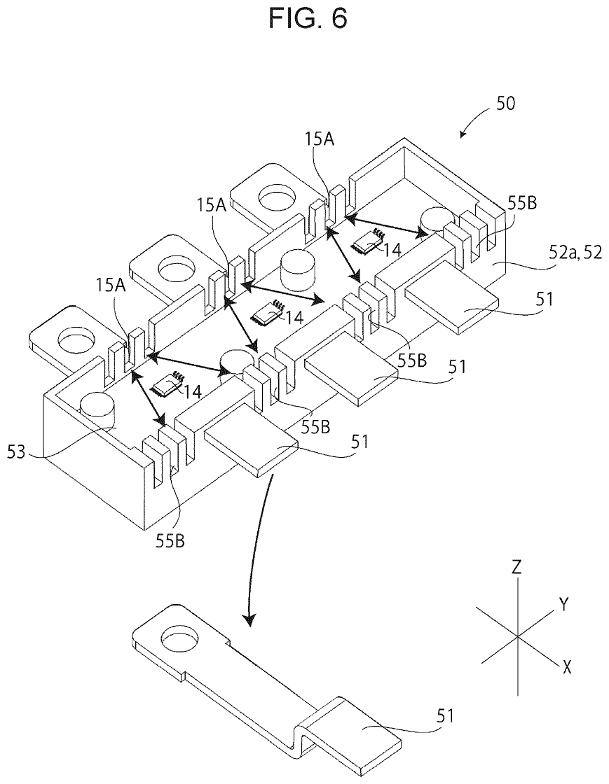

FIG. 6 is a perspective view of a current sensor 50 according to another modification. Although the drawing illustrates a state where the cover member 12b and the substrate 19 are omitted for convenience of description, the current sensor 50 includes the cover member 12b as with the current sensor 10, and the magnetic detectors 14 are provided on the substrate 19.

The current sensor 50 is different from the current sensor 10 in that the current sensor 50 includes busbars 51 having a different shape from the busbars 11 and second vents 55B are provided at positions corresponding to the shape of the busbars 51. Other components of the current sensor 50 are the same as those of the current sensor 10.

As illustrated in FIG. 6, the busbars 51 are bent in the current sensor 50. In this case, the second vents 55B cannot be formed at positions overlapping the first vents 15A in the X-axis direction and overlapping the busbars 51 in the Z-axis direction. In the current sensor 50, therefore, the first vents 15A are formed at positions overlapping the busbars 51 in the Z-axis direction, and the second vents 55B are formed on both sides of the busbars 51 in the Y-axis direction. As a result, airflow is formed in a storage space 53 diagonally with respect to a width direction (X-axis direction) of a case member 52a (housing 52). When the first vents 15A and the second vents 55B are configured in this manner, too, it is possible to discharge hot air from the storage space 53 to the outside of the storage space 53 using airflow caused by a difference in temperature from the outside and suppress a decrease in the measurement accuracy of the current sensor 50 caused by an increase in the temperature of the magnetic detectors 14. As with the second vents 55B, the first vents 15A may be formed on both sides of the busbars 51 in the Y-axis direction.

### Third Modification

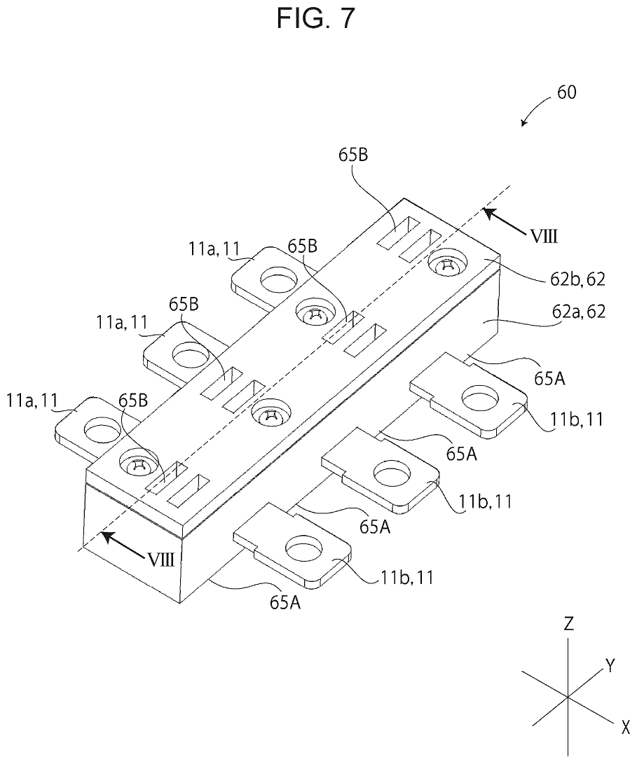

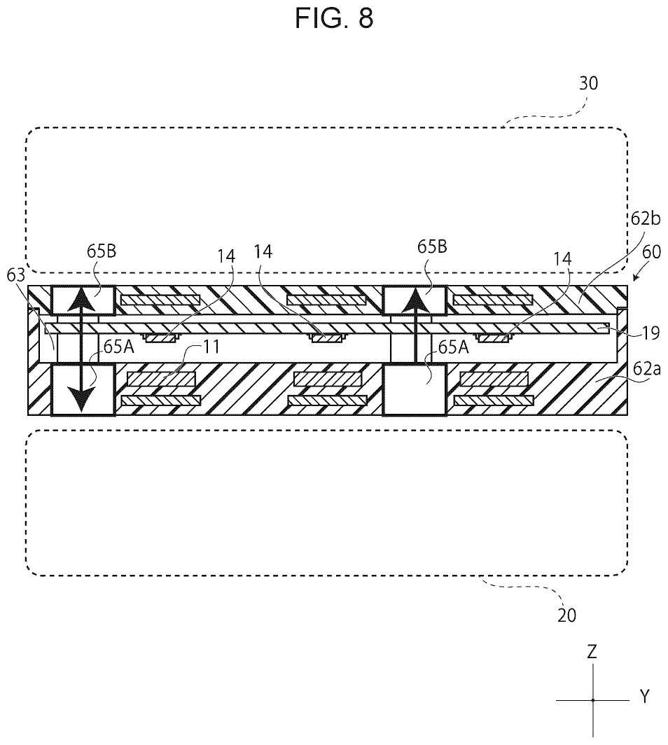

FIG. 7 is a perspective view of a current sensor 60 according to another modification, and FIG. 8 is a cross-sectional view cut from the current sensor 60 of FIG. 7 in a YZ plane along line VIII-VIII. The current sensor 60 is different from the current sensor 10 in terms of positions in a housing 62 at which first vents 65A and second vents 65B are provided. Other components of the current sensor 60 are the same as those of the current sensor 10.

The first unit 20 to which the ends 11a of the busbars 11 are connected and the second unit 30 to which the other ends 11b are connected are arranged at various positions in accordance with design of a product. The positions at which the first unit 20 and the second unit 30 are arranged, therefore, are not limited to the X-axis direction of the current sensor 10 illustrated in FIG. 4.

The current sensor 60 illustrated in FIGS. 7 and 8 uses airflow caused by a difference in temperature when the first unit 20 including the cooling device 21 (see FIG. 4) is arranged on a case member 62a side in the Z-axis direction and the second unit 30 is arranged on a cover member 62b side in the Z-axis direction. In order to use external airflow, therefore, a bottom surface (a surface whose perpendicular line is parallel to the Z-axis) of the case member 62a has the first vents 65A, and an upper surface (a surface whose perpendicular line is parallel to the Z-axis) of the cover member 62b has the second vents 65B.

With this configuration, it is possible to discharge air heated by heat generated by the busbars 11 to the outside of a storage space 63 using airflow in the Z-axis direction indicated in FIG. 8 by a two-way arrow and suppress an increase in the temperature of the magnetic detectors 14. In order to improve heat exhaust efficiency of the storage space 13 based on movement of air in the Z-axis direction, holes penetrating through the substrate 19 in the Z-axis direction may be provided in part of the substrate 19. The substrate 19, however, is provided in the storage space 13 with a gap from the case member 62a provided therearound. Even if holes are not provided, therefore, heated air in the storage space 63 can be discharged to the outside using movement of air in the Z-axis direction.

The positions and the number of first vents 65A and second vents 65B may be appropriately set in accordance with the first unit 20 and the second unit 30. As with the current sensor 40 illustrated in FIG. 5, the first vents 65A may be provided only in a surface on the side facing the first unit.

### Fourth Modification

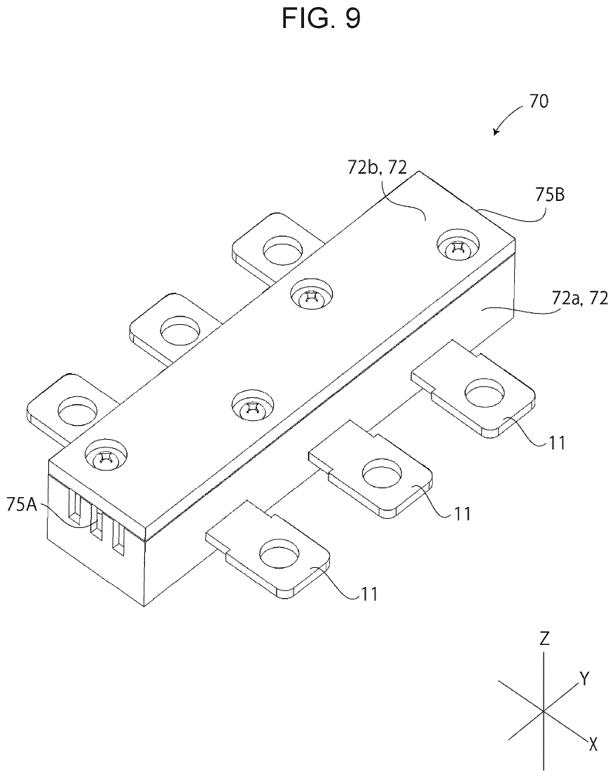

FIG. 9 is a perspective view of a current sensor 70 according to another modification, and first vents 75A and second vents 75B are provided in both surfaces of a case member 72a in the Y-axis direction perpendicular to a direction in which the busbars 11 extend. When the first unit 20 and the second unit 30 (see FIGS. 4 and 5) are provided on both sides of a housing 72 formed by the case member 72a and a cover member 72b in a longitudinal direction (Y-axis direction) of the housing 72, therefore, heated air in the storage space 13 can be discharged to the outside using movement of air caused by a difference in temperature.

As described as the second to fourth modifications, the first unit and the second unit are provided at various positions in accordance with design, and vents are provided at various positions in accordance with arrangement of the first unit and the second unit. With this configuration, it is possible to discharge air heated by heat in a storage space of a housing to the outside using airflow caused by a difference in temperature, prevent an increase in temperature in the storage space due to heat generated by busbars when a large current is measured, and maintain the measurement accuracy of a current sensor.

### Fifth Modification

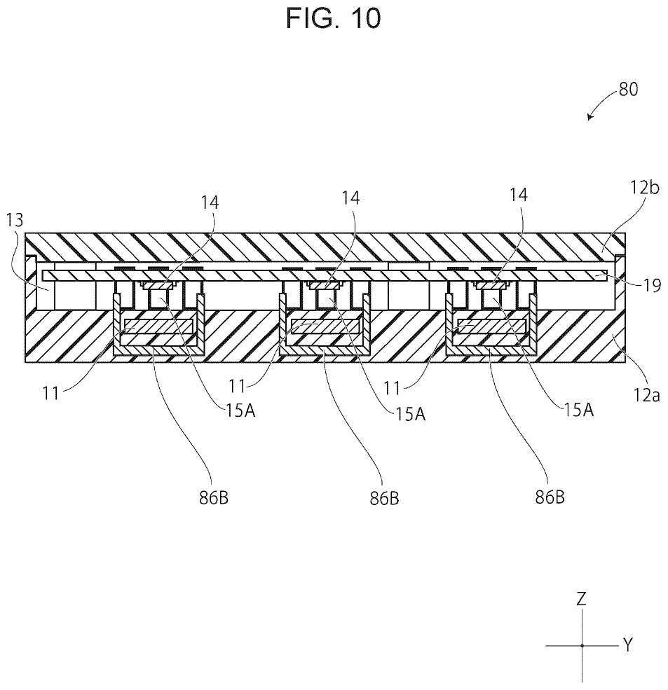

FIG. 10 is a cross-sectional view of a current sensor 80 according to another modification, and illustrates a structure of a part corresponding to a part of the current sensor 10 in FIG. 1 indicated by line III-III. The current sensor 80 is different from the current sensor 10 in that the current sensor 80 does not include the plate-like first shielding members 16A and includes, instead of the plate-like second shielding members 16B, second shielding members 86B whose cross-sectional shape when cut along a direction perpendicular to the direction (X-axis direction) in which the busbars 11 extend is a U-shape, and other components are the same as those of the current sensor 10.

The second shielding members 86B are arranged in such a way as to surround, when viewed in the direction (X-axis direction) in which the busbars 11 extend, the busbars 11 from three sides other than a side on which the magnetic detectors 14 are arranged. That is, the busbars 11 are surrounded by the second shielding members 86B from both sides of the busbars 11 in the Y-axis direction and a side opposite the side in the Z-axis direction on which the magnetic detectors 14 are arranged. As a result, it is possible to suppress an effect of adjacent busbars 11 other than a busbar 11 that each magnetic detector 14 faces, using the corresponding second shielding member 86B. It is therefore possible to suppress an effect of an external magnetic field upon the magnetic detectors 14 and improve the detection accuracy of the current sensor 80.

### Sixth Modification

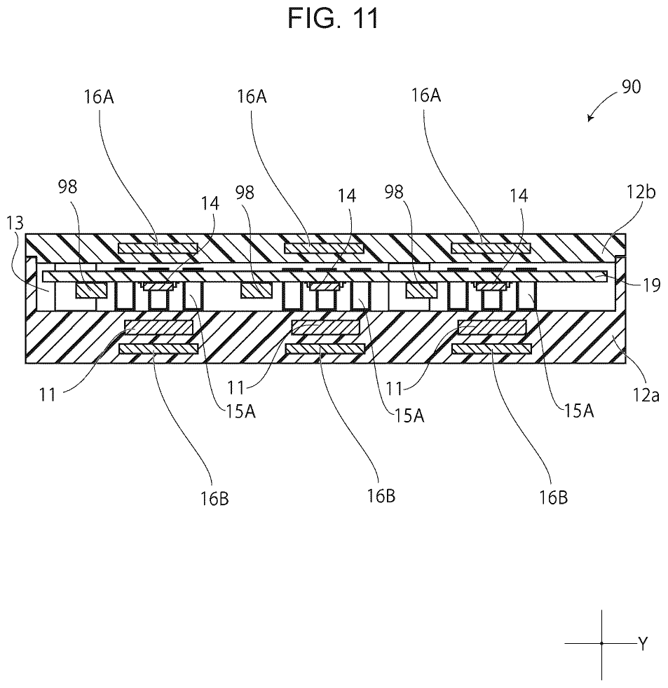

FIG. 11 is a cross-sectional view of a current sensor 90 according to another modification. The current sensor 90 is different from the current sensor 10 in that electronic components 98 different from the magnetic detectors 14 are arranged in the storage space 13 along with the magnetic detectors 14, and other components are the same as those of the current sensor 10. As the electronic components 98, for example, components of IC chips such as capacitors and resistors may be used.

Because the housing 12 has the first vents 15A and the second vents 15B in the current sensor 90 as in the current sensor 10, air heated by heat generated by the busbars 11 can be discharged to the outside of the storage space 13 using airflow outside the storage space 13. It is therefore possible to prevent increases in temperature of the magnetic detectors 14 and the electronic components 98 due to heat generated by the busbars 11 and a decrease in detection accuracy of the current sensor 90.

The embodiment disclosed herein is an example in all respects, and the scope of the present invention is not limited to this embodiment. The scope of the present invention is defined not by the description of only the above embodiment but by the claims, and intended to include all modifications within a meaning and a scope equivalent to the claims.

The present invention is effective as a current sensor that is capable of suppressing an increase in temperature of magnetic detectors and a decrease in measurement accuracy of the current sensor by discharging air heated by heat generated by a large current flowing through busbars to the outside of a storage space and that measures a current between, for example, a motor and an inverter.

What is claimed is:

1. A current sensor comprising:
a busbar through which a current to be measured flows;
a magnetic detector capable of detecting a magnetic field generated when the current to be measured flows through the busbar; and
a housing that has a storage space storing the magnetic detector and with which part of the busbar is integrated,
wherein the current sensor is capable of measuring a current value of the current to be measured from the magnetic field detected by the magnetic detector,
wherein an end of the busbar is connected to an external first unit including a cooling device and another end of the busbar is connected to an external second unit whose temperature is higher than temperature of the first unit, and
wherein the housing has a first vent penetrating from an inside of the storage space to an outside on a side facing the first unit.

2. The current sensor according to claim 1,
wherein the housing has, in addition to the first vent, a second vent penetrating from the inside of the storage space to the outside on a side facing the second unit.

3. The current sensor according to claim 2,
wherein the magnetic detector is arranged between the first vent and the second vent.

4. The current sensor according to claim 1,
wherein the magnetic detector is arranged at a position facing the busbar.

5. The current sensor according to claim 1, further comprising:
plate-like shielding members capable of suppressing disturbance noise applied to the magnetic detector,
wherein the shielding members include a first shielding member arranged on a side of the magnetic detector opposite a side on which the busbar is arranged and a second shielding member paired with the first shielding member and arranged on a side of the busbar opposite a side on which the magnetic detector is arranged.

6. The current sensor according to claim 1, further comprising:
a shielding member capable of suppressing disturbance noise applied to the magnetic detector,
wherein a cross-sectional shape of the shielding member when cut along a surface perpendicular to a direction in which the busbar extends is a U-shape, and the shielding member is arranged in such a way as to surround, when viewed in the direction in which the busbar extends, the busbar from both sides of the busbar in a direction perpendicular to a direction in which the busbar and the magnetic detector overlap and a side of the busbar opposite a side in the direction in which the busbar and the magnetic detector overlap on which the magnetic detector is arranged.

7. The current sensor according to claim 1, further comprising:
an electronic component different from the magnetic detector,
wherein the electronic component is arranged in the storage space.

8. A current control system comprising:
the current sensor according to claim 1;
the first unit; and
the second unit.

9. The current control system according to claim 8,
wherein the first unit is an inverter including the cooling device, and the second unit is a motor.
